(19) United States
(12) Patent Application Publication
(10) Pub. No.: US 2021/0028052 A1
(43) Pub. Date: Jan. 28, 2021

(54) LIFT PIN ALIGNMENT METHOD AND ALIGNMENT APPARATUS AND SUBSTRATE PROCESSING APPARATUS

(71) Applicant: SAMSUNG ELECTRONICS CO., LTD., Suwon-si, (KR)

(72) Inventors: Jinho SO, Seoul (KR); Keonwoo KIM, Seongnam-si (KR); Joohee KIM, Ansan-si (KR); Minsung KIM, Suwon-si (KR); Eultae KIM, Suwon-si (KR); Bora YOON, Goyang-si, (KR)

(21) Appl. No.: 16/846,792

(22) Filed: Apr. 13, 2020

(30) Foreign Application Priority Data
Jul. 25, 2019 (KR) 10-2019-0090330

(51) Int. Cl. H01L 21/687; H01L 21/67; H01L 21/68; H01J 37/32

(52) U.S. Cl. CPC H01L 21/68742; H01L 21/67259; H01J 2237/20235; H01J 37/32715; H01J 2237/24578; H01L 21/682

(57) ABSTRACT

A substrate processing apparatus and a lift pin alignment apparatus, the substrate processing apparatus including a chamber; a substrate plate on which the substrate is seatable; a plurality of movable lift in the substrate plate to support the substrate; a leveling sensor configured to be loadable in the chamber on the lift pins; a controller configured to receive measurement values of roll (φ) and pitch (θ) of a plane of the lift pins to calculate a rotation matrix (T) of the plane from the measurement values of roll (φ) and pitch (θ), and to calculate travel distances of the lift pins for leveling the plane to be parallel with a horizontal reference plane by using the rotation matrix (T) and to output a lift pin control signal for aligning the lift pins; and a lift pin driver to move the lift pins according to the lift pin control signal.

### CROSS-REFERENCE TO RELATED APPLICATION

Korean Patent Application No. 10-2019-0090330, filed on Jul. 25, 2019, in the Korean Intellectual Property Office, and entitled: “Lift Pin Alignment Method and Alignment Apparatus, and Substrate Processing Apparatus,” is incorporated by reference herein in its entirety.

### BACKGROUND

### 1. Field

Embodiments relate to a lift pin alignment method and alignment apparatus, and a substrate processing apparatus.

### 2. Description of the Related Art

A substrate processing apparatus for performing semiconductor unit processes for manufacturing of photomasks or semiconductor devices may include a substrate plate within a chamber, on which a substrate is seatable. A plurality of lift pins for lifting the substrate may be installed in the substrate plate to be spaced apart from each other.

### SUMMARY

The embodiments may be realized by providing a substrate processing apparatus including a chamber to provide a space for processing a substrate; a substrate plate within the chamber and on which the substrate is seatable; a plurality of lift pins protruding from within the substrate plate to support the substrate, the plurality of lift pins being configured to move upwardly and downwardly; a leveling sensor configured to be loadable in the chamber on the plurality of lift pins that protrude from the substrate plate; a controller configured to receive measurement values of roll (φ) and pitch (θ) representing an angle of a plane of the plurality of lift pins from the leveling sensor to calculate a rotation matrix (T) of the plane from the measurement values of roll (φ) and pitch (θ), to calculate travel distances of the lift pins for leveling the plane to be parallel with a horizontal reference plane by using the rotation matrix (T), and to output a lift pin control signal for aligning the plurality of lift pins in a horizontal plane; and a lift pin driver configured to move the plurality of lift pins according to the lift pin control signal.

The embodiments may be realized by providing a substrate processing apparatus including a chamber to provide a space for processing a substrate; a substrate plate within the chamber and on which the substrate is seatable; a plurality of lift pins protruding from within the substrate plate, the plurality of lift pins being configured to move upwardly and downwardly; a leveling sensor configured to be loadable in the chamber on the plurality of lift pins that protrude from the substrate plate; a controller configured to calculate an inclination of a plane of the plurality of lift pins with respect to a horizontal reference plane based on sensing values from the leveling sensor and to output a lift pin control signal for leveling the plurality of lift pins in a horizontal plane; and a lift pin driver configured to move the plurality of lift pins by travel distances according to the lift pin control signal.

The embodiments may be realized by providing a lift pin alignment apparatus including a leveling sensor on a plurality of lift pins protruding from a substrate plate to detect an inclination of a plane of the lift pins with respect to a horizontal reference plane; a controller configured to calculate the inclination of the plane of the lift pins with respect to the horizontal reference plane based on sensing values from the leveling sensor and to output a lift pin control signal for leveling the lift pins in a horizontal plane; and a lift pin driver configured to move the lift pins by travel distances according to the lift pin control signal.

### BRIEF DESCRIPTION OF THE DRAWINGS

Features will be apparent to those of skill in the art by describing in detail exemplary embodiments with reference to the attached drawings in which:

FIG. 1 illustrates a cross-sectional view of a substrate processing apparatus in accordance with example embodiments.

FIG. 2 illustrates a perspective view of lift pins and a substrate plate of FIG. 1.

FIG. 3 illustrates a controller connected to a lift pin device of the substrate processing apparatus of FIG. 1.

FIG. 4 illustrates a plan view of the substrate plate of FIG. 1.

FIG. 5 illustrates a block diagram of a lift pin alignment apparatus in accordance with example embodiments.

FIGS. 6 and 7 illustrate plan views of a leveling sensor in accordance with example embodiments.

FIG. 8 illustrates a perspective view of a leveling sensor on the raised lift pins of FIG. 2.

FIG. 9 illustrates a cross-sectional view of an inclined state of the leveling sensor on the lift pins of FIG. 8.

FIG. 10 illustrates a perspective view of rotations of the inclined leveling sensor of FIG. 9.

FIG. 11 illustrates a flow chart of a lift pin alignment method in accordance with example embodiments.

FIG. 12 illustrates a graph of a plane which lift pins constitute and travel distances of the lift pins for leveling.

FIG. 13 illustrates a flow chart of a method of manufacturing a photomask in accordance with example embodiments.

### DETAILED DESCRIPTION

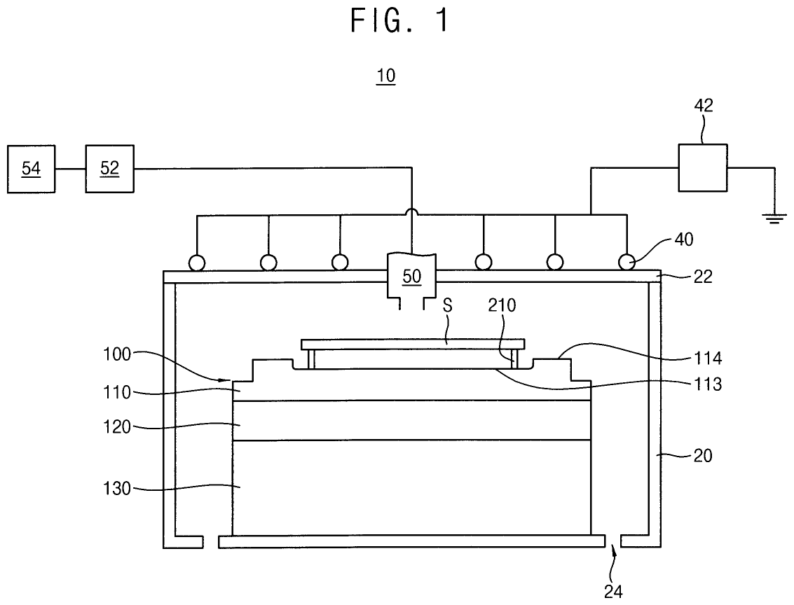

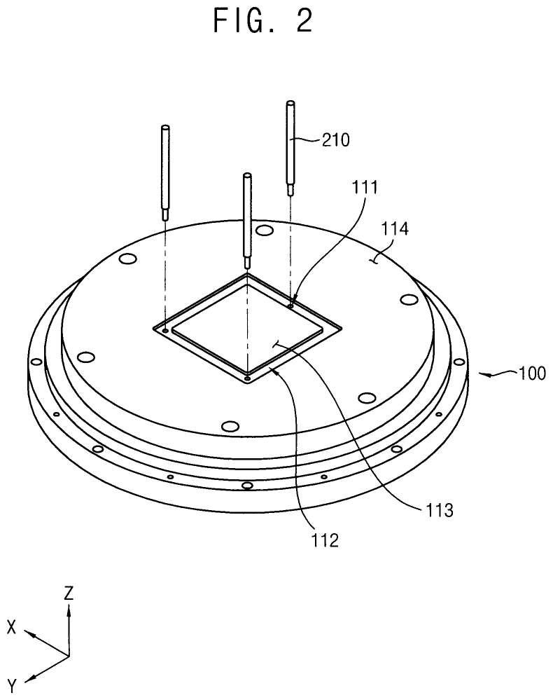

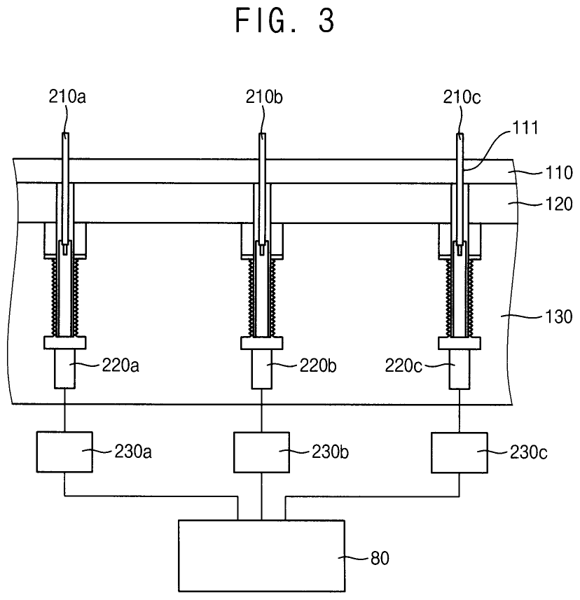

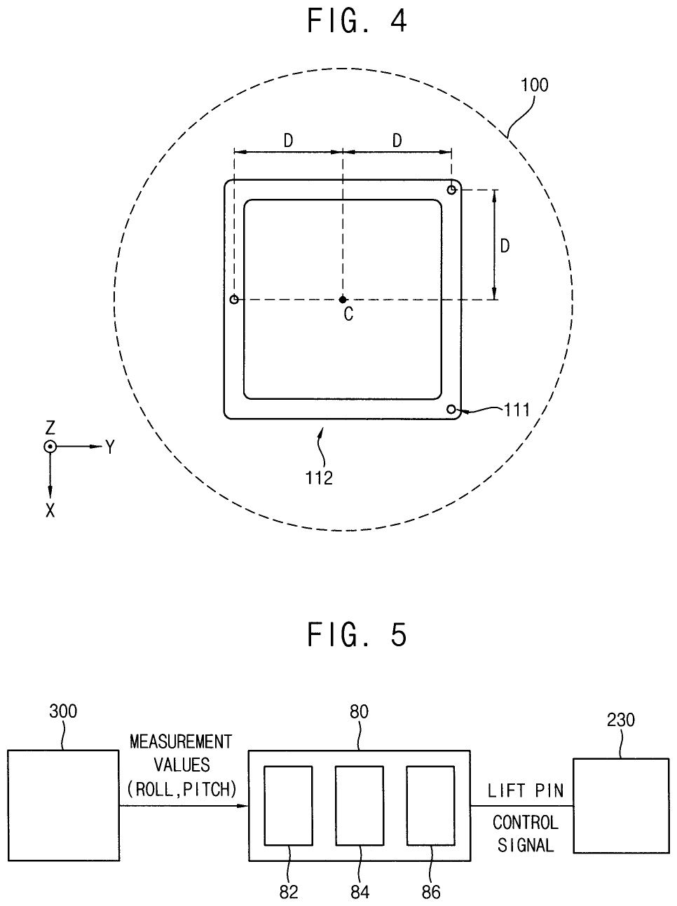

FIG. 1 illustrates a cross-sectional view of a substrate processing apparatus in accordance with example embodiments. FIG. 2 illustrates a perspective view of lift pins on a substrate plate of FIG. 1. FIG. 3 illustrates a controller connected to a lift pin device of the substrate processing apparatus of FIG. 1. FIG. 4 illustrates a plan view of the substrate plate of FIG. 1.

Referring to FIGS. 1 to 4, a substrate processing apparatus 10 may include a chamber 20 configured to provide a space for processing a substrate S (such as photomask substrate or wafer W) and a substrate support 100 within the chamber 20 and configured to support the substrate. The substrate support 100 may include a substrate plate (on which the substrate is loadable or seatable) and a lift pin device having a plurality of lift pins 210 which is movable upwardly and downwardly (e.g., in a vertical Z direction) within the substrate plate to support the substrate. In addition, the substrate processing apparatus 10 may further include, e.g., a plasma power supply, a bias power supply, a gas supply, and an exhaust portion.

In an implementation, the substrate processing apparatus 10 may be a plasma processing apparatus that etches the substrate using plasma. In an implementation, the substrate processing apparatus 10 may be an apparatus that etches a layer on a substrate such as photomask substrate within the chamber 20, with, e.g., an inductively coupled plasma (ICP), generated within the chamber 20. In an implementation, capacitively coupled plasma, microwave plasma, or the like may be generated by the substrate processing apparatus. In an implementation, the substrate processing apparatus may be, e.g., a deposition apparatus, a cleaning apparatus, or the like. In an implementation, substrates processed by the substrate processing apparatus 10 include, e.g., a semiconductor substrate, a glass substrate, or the like.

The chamber 20 may provide a sealed space where a plasma etching process is performed on the substrate. The chamber 20 may include a metal, e.g., aluminum, stainless steel, or the like. The chamber 20 may include a cover 22 covering an upper portion of the chamber 20. The cover 22 may form an airtight seal with the upper portion of the chamber 20. The cover 22 may include a dielectric window.

In an implementation, the substrate support 100 may be installed within the chamber 20 to support the substrate S. The substrate support 100 may be provided as an electrostatic chuck for holding the substrate S using electrostatic force. The substrate support 100 may include, e.g., a support plate 110, an insulation plate 120, and a lower cover 130.

The support plate 110 may be positioned at one, e.g., an upper, portion or side of the substrate support 100. The support plate 110 may include an electrostatic electrode therein. The electrostatic electrode may be electrically connected to a DC power source via an ON-OFF switch. When the ON-OFF switch is turned ON, the electrostatic electrode may apply an electrostatic force on the substrate S on the support plate 110, and thus, the substrate S may be held on the support plate 110 by the electrostatic force.

The insulation plate 120 may be between the support plate 110 and the lower cover 130 to electrically insulate between the support plate 110 and the lower cover 130.

The lower cover 130 may be positioned at another, e.g., a lower, portion or side of the substrate support 100. The lower cover 130 may have a space therein, of which an upper end (e.g., facing the insulation plate 120) is open. The upper end of the lower cover 130 may be covered by the insulation plate 120. A driving mechanism including a lift pin actuator for moving the lift pin 210 upward and downward (e.g., in the vertical Z direction) may be in the space of the lower cover 130.

In an implementation, a heater and a plurality of pathways may be in the support plate 110. The heater may be electrically connected to a power source to heat the substrate S through the support plate 110. The heater may include a spiral coil. The pathway may be used as a channel through which a heat transfer fluid circulates. The pathway may be formed in the support plate 110 to have a spiral shape.

In an implementation, the plasma power supply may include a source RF power source 42 to apply a plasma source power output to an upper electrode 40. The source RF power source 42 may generate a radio frequency (RF) signal. The upper electrode 40 may include a coil having a spiral shape or a concentric shape. The bias power supply may include a bias RF power source to apply a bias source power output to a lower electrode in the substrate support 100.

The gas supply may include a gas supply tube 50, a flow rate controller 52, and a gas supply source 54. The gas supply may supply different process gases into the chamber 20.

When a radio frequency power output having a predetermined frequency (e.g., 13.56 MHz) is applied to the upper electrode 40, an electromagnetic field induced by the upper electrode 40 may be applied to a source gas supplied into the chamber 20 to generate plasma. When the bias power is applied to the lower electrode, the support plate 110 may attract plasma atoms or ion generated within the chamber 20.

The exhaust portion may include an exhaust line connected to an exhaust port 24 in a bottom of the chamber 20. The exhaust portion may include a vacuum pump to control a pressure of the chamber such that the processing space inside the chamber 20 may be depressurized to a desired vacuum level. Process by-products and residual process gases formed during the process may be discharged through the exhaust line.

In an implementation, the lift pin 210 may receive the substrate S transferred into the processing space within the chamber 20 by a transfer mechanism and move to the support plate 110. The lift pin 210 may seat or accommodate the substrate S on the support plate 110 or lift the substrate S from the support plate 110. For example, a plurality of the lift pins 210 may be provided. The lift pin 210 may be movable upwardly and downwardly within or through a pin hole 111 that penetrates through the support plate 110.

As illustrated in FIGS. 2 and 4, a receiving recess 112 for receiving the substrate S may be in an upper surface 114 of the support plate 110. The receiving recess 112 may have a rectangular shape corresponding to a shape of the substrate S. The receiving recess 112 may have a support surface 113 on which the substrate S is supportable. The support surface 113 may be positioned lower than the upper surface 114 of the support plate 110 (e.g., may be recessed within the support plate 110).

A first lift pin 210a may be in the pin hole 111 at a middle point of a first side of the receiving recess 112, second and third lift pins 210b, 210c may be in the pin holes 111 at both end portions of a second side of the receiving recess 112 that is opposite to the first side, respectively (e.g., at adjacent corners of the receiving recess 112).

For example, the first lift pin 210a may be spaced apart from a center C of the receiving recess 112 by a first distance D (e.g., in a Y direction that is perpendicular to the vertical Z direction), and a distance 2D (e.g., in a X direction that is perpendicular to the Y direction) between the second lift pin 210b and the third lift pin 210c may be two times the first distance D. The first distance D may range from, e.g., 50 mm to 90 mm.

In an implementation, as illustrated in FIG. 3, the substrate processing apparatus 10 may include a lift pin device that elevates the lift pins 210 (e.g., that independently adjusts a vertical position of the individual lift pins 210 in the vertical Z direction). The lift pin device may include first to third actuators 220a, 220b, 220c (for moving the first to third lift pins 210a, 210b, 210c upward and downward, respectively) and an actuator driver 230 having first to third drivers 230a, 230b, 230c for driving the first to third actuators 220a, 220b, 220c, respectively. The first to third drivers 230a, 230b, 230c may be connected to a controller 80 for controlling operations of the lift pins.

The first to third drivers 230a, 230b, 230c may elevate (e.g., vertically move in the Z direction) the first to third lift pins independently according to a lift pin control signal from the controller 80. The first driver 230a may move the first lift pin 210a in the vertical direction (Z direction) by a first travel distance according to a first lift pin control signal from the controller 80. The second driver 230b may move the second lift pin 210b in the vertical direction (Z direction) by a second travel distance according to a second lift pin control signal from the controller 80. The third driver 230c may move the third lift pin 210c in the vertical direction (Z direction) by a third travel distance according to a third lift pin control signal from the controller 80.

In an implementation, the controller 80 may control operations of various components connected to the controller 90 for controlling the substrate processing apparatus 10. The controller 80 may include a processor, a memory, and one or more interfaces as a control module. The controller 80 may control the components connected to the controller 80 based on sensing values.

In an implementation, the controller may control the components of the substrate processing apparatus 10 to perform a plasma etch process on the photomask substrate S for manufacturing a photomask.

In order to perform leveling of the lift pins 210, the controller 80 may control that the chamber 20 may remain in a vacuum state and a leveling sensor 300 may be loaded on raised lift pins 210 within the chamber 20, may analyze coplanarity (e.g., planarity or inclination) of the lift pins 210 with respect to a reference surface based on detection signals received from the leveling sensor 300 and output the lift pin control signal for leveling the lift pins 210 to the actuator driver 230. When a horizontal inclination of the plane of the lift pins 210 is measured by the leveling sensor 300 loaded into the chamber 20, the controller 80 may control to maintain the chamber 20 in a vacuum state.

Hereinafter, an alignment apparatus for aligning a horizontal state of the lift pins using the leveling sensor 300 will be explained.

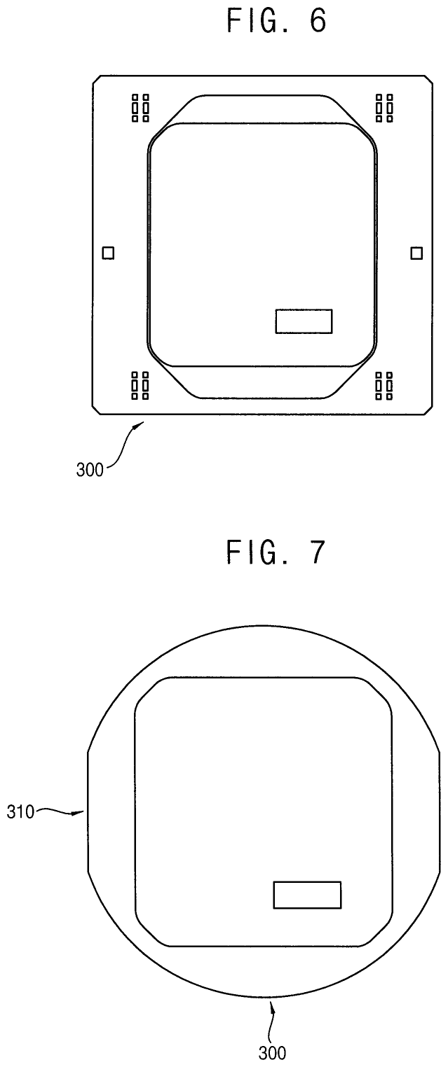

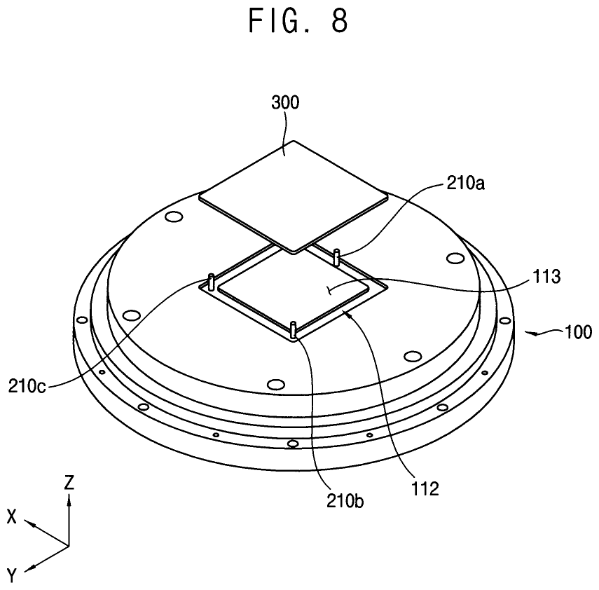

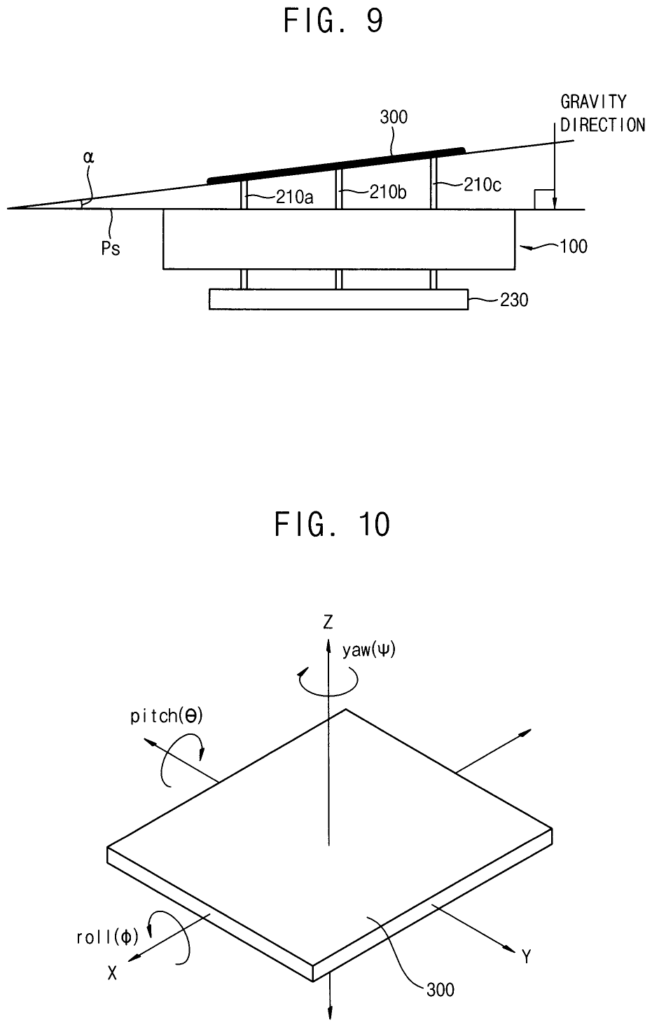

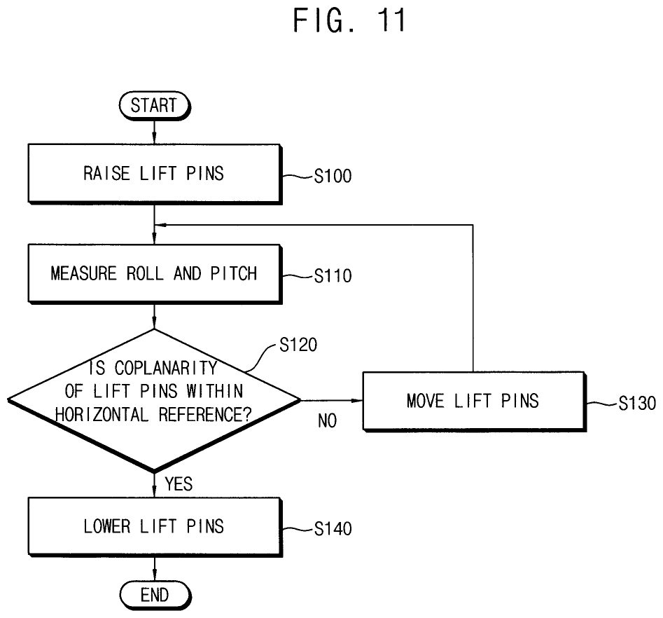

FIG. 5 illustrates a block diagram of a lift pin alignment apparatus in accordance with example embodiments. FIGS. 6 and 7 illustrate plan views of a leveling sensor in accordance with example embodiments. FIG. 8 illustrates a perspective view of a leveling sensor loaded on the raised lift pins of FIG. 2. FIG. 9 illustrates a cross-sectional view of an inclined state of the leveling sensor on the lift pins of FIG. 8. FIG. 10 illustrates a perspective view of rotations of the inclined leveling sensor of FIG. 9.

Referring to FIGS. 5 to 10, a lift pin alignment apparatus may include the leveling sensor 300, the controller 80, and the lift pin driver 230. The leveling sensor 300 may be on a plurality of raised lift pins 210a, 210b, 210c from a substrate plate to measure an inclination of a plane which the lift pins constitute (e.g., of a plane formed by the lift pins), with respect to a plane perpendicular to a direction of a gravitational force (e.g., a horizontal X-Y reference plane). The controller 80 may calculate the inclination of the plane of the lift pins based on sensing values received from the leveling sensor 300 and may output a lift pin control signal for aligning the lift pins in a horizontal plane. The lift pin driver 230 may move the lift pins according to the lift pin control signal.

In an implementation, the leveling sensor 300 may have a shape corresponding to a substrate to be processed on the substrate plate. In an implementation, as illustrated in FIG. 6, the leveling sensor 300 may have a mask-type leveling sensor having a square shape corresponding to a photomask substrate. In an implementation, as illustrated in FIG. 7, the leveling sensor 300 may be a wafer-type leveling sensor having a disk shape corresponding to a wafer.

The mask-type leveling sensor 300 may be supported by a transfer mechanism, e.g., an end effector, and may be slid into a chamber 20 of a substrate processing apparatus 10 to be disposed on the first to third lift pins 210a, 210b, 210c.

For example, the end effector of the transfer mechanism may support the leveling sensor 300 and slide over the substrate plate. The first to third lift pins 210a, 210b, 210c may be raised to support the leveling sensor 300, and then, the end effector may be retreated to place the leveling sensor 300 on the raised first to third lift pins 210a, 210b, 210c.

As illustrated in FIGS. 9 to 10, the mask-type leveling sensor 300 on the raised first to third lift pins 210a, 210b, 210c may have a plane the same as the plane which the raised first to third lift pins 210a, 210b, 210c constitute (e.g., the plane defined by points of the raised first to third lift pins 210a, 210b, 210c). When the raised first to third lift pins 210a, 210b, 210c have different heights, the leveling sensor 300 on the raised first to third lift pins 210a, 210b, 210c may be inclined at an angle (α) with respect to a reference plane (Ps). The inclination of the leveling senor 300 may be represented by Euler angles, that is, roll (φ), pitch (θ) and yaw (ψ).

The mask-type leveling sensor 300 may include MEMS (microelectromechanical systems) inclinometers that measure the inclination of orthogonal axes of the photomask substrate with respect to Earth's gravity direction.

As illustrated in FIG. 5, the leveling sensor 300 may transmit measurement values of roll (φ) and pitch (θ) representing an angle of the plane of the first to third lift pins 210a, 210b, 210c, to the controller 80 in real time via, e.g., wireless communication. In an implementation, the leveling sensor 300 may use wireless communication, e.g., WIFI, RF communications, or the like.

The controller 80 may detect a horizontal state (e.g., coplanarity or planarity relative to the X-Y reference plane or inclination) of the first to third lift pins 210a, 210b, 210c based on the measurement values of roll (φ) and pitch (θ) transmitted from the leveling sensor 300. For example, it may be determined whether the planarity of the first to third lift pins 210a, 210b, 210c is within a horizontal reference range (e.g., whether the plane of the first to third lift pins 210a, 210b, 210c aligns with the X-Y reference plane or is inclined).

If it is determined that the plane of the first to third lift pins 210a, 210b, 210c deviates from the horizontal reference range, the controller 80 may output a lift pin control signal for aligning the first to third lift pins in a horizontal plane.

For example, the controller 80 may include a horizontal state determiner 82, a travel distance calculator 84, and an output portion 86.

The horizontal state determiner 82 may receive the measurement values of roll (φ) and pitch (θ) from the leveling sensor 300 and determine whether the planarity of the first to third lift pins 210a, 210b, 210c is within the horizontal reference range based on the received measurement values.

The horizontal state determiner 82 may calculate a rotation matrix (T) using a first rotation matrix (Rx) rotated by φ degrees about an X axis from the roll (φ) measurement value and a second rotation matrix (Ry) rotated by θ degrees about a Y axis from the pitch (θ) measurement value. The horizontal state determiner 82 may calculate coordinate values (z1, z2, z3) of the first to third lift pins 210a, 210b, 210c with respect to the reference plane (Ps) from the rotation matrix.

The travel distance calculator 84 may calculate travel distances of the first to third lift pins 210a, 210b, 210c for leveling the inclined plane to the horizontal plane.

In an implementation, the travel distance calculator 84 may calculate final travel distances (Δz1′, Δz2′, Δz3′) to converge on an average height of the first to third lift pins 210a, 210b, 210c. The final travel distances may be obtained by subtracting a mean value (z_m) of the first to third lift pins 210a, 210b, 210c, e.g., the central value of height values of the first to third lift pins, from the travel distances (Δz1, Δz2, Δz3) respectively.

The output portion 86 may output first to third lift pin control signals in proportion to the calculated final travel distances (Δz1′, Δz2′, Δz3′) to first to third drivers 230a, 230b, 230c respectively.

The first driver 230a may move the first lift pin 210a in the vertical direction (Z direction) by a first travel distance (Δz1′) according to the first lift pin control signal from the controller 80. The second driver 230b may move the second lift pin 210b in the vertical direction (Z direction) by a second travel distance (Δz2′) according to a second lift pin control signal from the controller 80. The third driver 230c may move the third lift pin 210c in the vertical direction (Z direction) by a third travel distance (Δz2′) according to a third lift pin control signal from the controller 80.

In an implementation, the controller 80 may determine an alignment state of the leveling sensor 300 on the substrate plate, and, if it is determined that the leveling sensor 300 is misaligned, the controller 80 may transmit a control signal for aligning the leveling sensor 300 to the driver 230. Whether a direction in which the leveling sensor 300 is disposed is aligned with a predetermined direction (X axis direction or Y axis direction) may be determined to decide the alignment state of the leveling sensor 300.

For example, the mask-type leveling sensor 300 may be received in the receiving recess 112 of a support plate 110, and then, one of the first to third lift pins 210a, 210b, 210c may be raised. Then, measurement values of roll (φ) and pitch (θ) may be obtained from the leveling sensor 300 to determine whether an alignment (sliding) direction of the leveling sensor 300 is aligned with XYZ coordinates of the substrate plate. If only the roll (φ) measurement value were detected, it could be determined that the leveling sensor 300 is received precisely. When both the roll (φ) and pitch (θ) measurement values are detected, it may be determined that the leveling sensor 300 is misaligned, and the controller 80 may control that the leveling sensor 300 may be unloaded from the chamber 20 and then after performing an alignment correction, the leveling sensor 300 may be loaded again into the chamber 20.

In case of the wafer-type leveling sensor 300, a position of a flat 310 or notch of the wafer-type leveling sensor 300 may be detected to decide the alignment state of the leveling sensor 300.

As mentioned above, the lift pin alignment apparatus may detect the horizontal state of the first and third lift pins 210a, 210b, 210c based on the measurements (roll (φ) and pitch (θ)) representing rotations with respect to the reference plane (Ps) received from the leveling sensor 300 on the first to third lift pins 210a, 210b, 210c, and calculate the travel distances of the first to third lift pins 210a, 210b, 210c for aligning the first to third lift pins in a horizontal plane. The first to third lift pins 210a, 210b, 210c may be moved by the calculated travel distances to align the heights of the first to third lift pins 210a, 210b, 210c.

For example, by using the mask-type or wafer-type leveling sensor 300, the leveling of the lift pins may be automatically performed without stopping equipment and removing vacuum state.

Further, by adjusting the lift pins to converge on the average height of the lift pins, during leveling of the lift pins, the lift pins may be prevented from deviating from a limit height.

Hereinafter, a method of aligning a horizontal state of lift pins using the alignment apparatus in FIG. 10 will be explained.

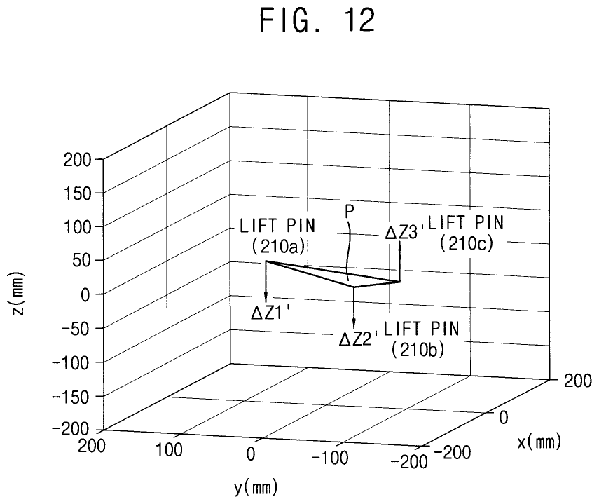

FIG. 11 illustrates a flow chart of a lift pin alignment method in accordance with example embodiments. FIG. 12 illustrates a graph of a plane which lift pins constitute and travel distances of the lift pins for leveling.

FIGS. 1, 3, 5, 9 and 10 to 12, first, the first to third lift pins 210a, 210b, 210c may be raised to support the leveling sensor 300 (S100).

In an implementation, before performing a process on a substrate S within the chamber 20, the leveling sensor 300 may be loaded into the chamber 20 to perform leveling of the lift pins.

For example, an end effector of a transfer mechanism may be slid over the substrate plate within the chamber 20, with the leveling sensor 300 supported on the end effector. The first to third lift pins 210a, 210b, 210c may be raised to support the leveling sensor 300 and the end effector may be retracted.

Then, roll (φ) and pitch (θ) of the leveling sensor 300 may be measured (S110), and a determination may be made as to whether the plane which the first to third lift pins 210a, 210b, 210c constitute is within a horizontal reference range (S120).

In an implementation, the leveling sensor 300 may transmit measurement values of roll (φ) and pitch (θ) (representing an angle of the plane which the first to third lift pins 210a, 210b, 210c constitute) to the controller 80 in real time via, e.g., wireless communication. The controller 80 may calculate a rotation matrix (T) using a first rotation matrix (Rx) rotated by φ degrees about the X axis from the roll (φ) measurement value and a second rotation matrix (Ry) rotated by θ degrees about the Y axis from the pitch (θ) measurement value.

The inclination of the leveling sensor 300 (which may be inclined at an angle (α) with respect to a ground surface, e.g., the horizontal X-Y reference plane) may include a rotation by roll (φ) about the X axis and a rotation by pitch (θ) about the Y axis. The rotation matrix (T) including the rotations on XYZ coordinate system may be obtained as follows.

The first rotation matrix (Rx) rotated by φ degrees about the X axis may be represented by following equation (1), the second rotation matrix (Ry) rotated by θ degrees about the Y axis may be represented by following equation (2), and the rotation matrix (T) may be represented by following equation (3).

$$\begin{matrix}Rx = [ \begin{matrix}1 & 0 & 0 \\ 0 & cos ϕ & sin ϕ \\ 0 & - sin ϕ & cos ϕ\end{matrix} ] & Equation ( 1 ) \\ Ry = [ \begin{matrix}cos θ & 0 & - sin θ \\ 0 & 1 & 0 \\ sin θ & 0 & cos θ\end{matrix} ] & Equation ( 2 ) \\ T = RyRx & Equation ( 3 )\end{matrix}$$

In a case in which coordinate values of the first to third lift pins 210a, 210b, 210c in the horizontal reference plane are (X1, Y1, Z1), (X2, Y2, Z2), (X3, Y3, Z3) (here, Z1=Z2=Z3=0), coordinate values ((x1, y1, z1), (x2, y2, z2), (x3, y3, z3)) of the first to third lift pins 210a, 210b, 210c of which the plane is inclined at angle (α) with respect to the horizontal reference plane may be obtained by following equation (4).

$$( \begin{matrix}x \\ y \\ z\end{matrix} ) = RyRx [ \begin{matrix}X \\ Y \\ Z\end{matrix} ] \qquad Equation ( 4 )$$

Each z1, z2, z3 of the first to third lift pins 210a, 210b, 210c may represent a distance in the vertical direction from the horizontal plane (reference plane).

Accordingly, travel distances (Δz1, Δz2, Δz3) of the first to third lift pins 210a, 210b, 210c for leveling the inclined plane to the horizontal plane may be calculated. The travel distances (Δz1, Δz2, Δz3) of the first to third lift pins 210a, 210b, 210c may be calculated by following equation (5).

$$( \begin{matrix}Δ z 1 \\ Δ z 2 \\ Δ z 3\end{matrix} ) = [ \begin{matrix}Z 1 - z 1 \\ Z 2 - z 2 \\ Z 3 - z 3\end{matrix} ] \qquad Equation ( 5 )$$

In an implementation, final travel distances (Δz1′, Δz2′, Δz3′) of the first to third lift pins 210a, 210b, 210c may be calculated such that heights of the first to third lift pins 210a, 210b, 210c converge on an average height of the first to third lift pins 210a, 210b, 210c. The final travel distances may be obtained by subtracting a mean value (z_m) of the first to third lift pins 210a, 210b, 210c from the travel distances (Δz1, Δz2, Δz3) respectively. The final travel distances (Δz1′, Δz2′, Δz3′) of the first to third lift pins 210a, 210b, 210c may be represented by following equation (6).

$$( \begin{matrix}Δ z {1}^{′} \\ Δ z {2}^{′} \\ Δ z {3}^{′}\end{matrix} ) = [ \begin{matrix}z\_ m - Δ z 1 \\ z\_ m - Δ z 2 \\ z\_ m - Δ z 3\end{matrix} ] \qquad Equation ( 6 )$$

As illustrated in FIG. 12, the first to third lift pins 210a, 210b, 210c may be moved by the final travel distances (Δz1′, Δz2′, Δz3′) respectively (S130).

For example, the controller 80 may output first to third lift pin control signals in proportion to the calculated final travel distances (Δz1′, Δz2′, Δz3′) to first to third drivers 230a, 230b, 230c respectively.

The first driver 230a may move the first lift pin 210a in the vertical direction (Z direction) by a first travel distance (Δz1′) according to the first lift pin control signal from the controller 80. The second driver 230b may move the second lift pin 210b in the vertical direction (Z direction) by a second travel distance (Δz2′) according to a second lift pin control signal from the controller 80. The third driver 230c may move the third lift pin 210c in the vertical direction (Z direction) by a third travel distance (Δz2′) according to a third lift pin control signal from the controller 80.

Then, S100 and S120 may be performed repeatedly to determine the horizontal state of the first to third lift pins 210a, 210b, 210c which have been moved according to the first to third lift pin control signals. When it is determined that the plane of the first to third lift pins 210a, 210b, 210c is within a horizontal reference range, the first to third lift pins 210a, 210b, 210c may be lowered (e.g., together) to terminate the leveling process (S140).

For example, when the measurement values of roll (φ) and pitch (θ) measured from the leveling sensor 300 are within ±0.005 degrees (e.g., if the plane of the lift pins is inclined by less than 0.005 degrees), it may be determined that the planarity satisfies the horizontal reference range, and then, the leveling process may be terminated.

If it is determined that the plane of the first to third lift pins 210a, 210b, 210c is not within the horizontal reference range, S130, S100 and S120 may be performed repeatedly.

In an implementation, after the leveling sensor 300 is disposed on the substrate plate, an alignment state of the leveling sensor 300 may be determined, and then, if it is determined that the leveling sensor 300 is misaligned, an alignment of the leveling sensor may be corrected.

For example, after a mask-type leveling sensor 300 is received in a receiving recess 112 of a support plate 110, one of the first to third lift pins 210a, 210b, 210c may be raised. Then, measurement values of roll (φ) and pitch (θ) may be obtained from the leveling sensor 300 to determine whether an alignment (sliding) direction of the leveling sensor 300 is aligned with XYZ coordinates of the substrate plate. For example, if only the roll (φ) measurement value were to be detected, it could be determined that the leveling sensor 300 is received precisely. In case that both the roll (φ) and pitch (θ) measurement values are detected, it may be accurately determined that the leveling sensor 300 is misaligned, and the controller 80 may control that the leveling sensor 300 may be unloaded from the chamber 20 and then after performing an alignment correction, the leveling sensor 300 may be loaded again into the chamber 20.

In case of a wafer-type leveling sensor 300, a position of a flat 310 or notch of the wafer-type leveling sensor 300 may be detected to decide the alignment state of the leveling sensor 300.

Hereinafter, a method of manufacturing a photomask using the substrate processing apparatus will be explained.

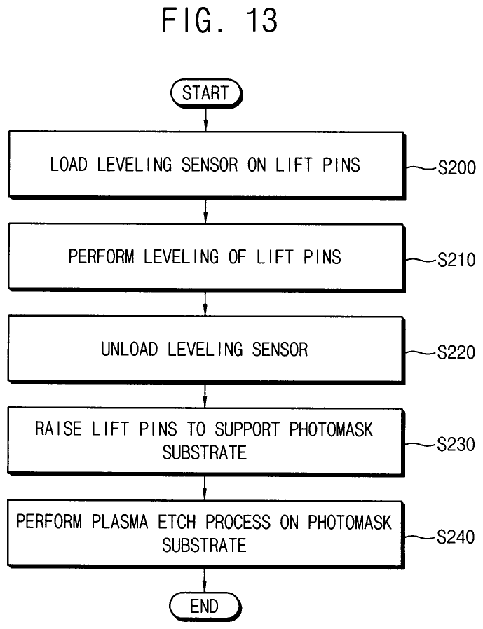

FIG. 13 illustrates a flow chart of a method of manufacturing a photomask in accordance with example embodiments.

Referring to FIGS. 1 to 13, the leveling sensor 300 may be loaded on the first to third lift pins 210a, 210b, 210c within the chamber (S200), a leveling process of the first to third lift pins 210a, 210b, 210c may be performed (S210), and then, the leveling sensor 300 may be unloaded from the chamber (S220).

In an implementation, before performing a process on a substrate S within the chamber 20, the leveling sensor 300 may be loaded into the chamber 20 to perform the leveling process of the lift pins.

S100 to S140 described with reference to FIG. 11 may be performed to complete the leveling process of the first to third lift pins 210a, 210b, 210c.

Then, the substrate S may be disposed on the first to third lift pins 210a, 210b, 210c (S230), and a plasma etch process may be performed on the photomask substrate S (S240).

In an implementation, after a light shielding layer is formed on the substrate having a square shape, a photoresist pattern for desired pattern exposure may be formed on the light shielding layer. The (photomask) substrate S having the photoresist pattern thereon may be loaded into the chamber 20 of the substrate processing apparatus 10.

For example, the photomask substrate S may be transferred by a transfer mechanism to be over the support plate 110, and then, the first to third lift pins 210a, 210b, 210c may be raised (e.g., together) from an upper surface of the support plate 110. A transfer robot may place the photomask substrate S on the raised first to third lift pins 210a, 210b, 210c, and then, the first to third lift pins 210a, 210b, 210c may be lowered into the pin hole 111 of the support plate 110 such that the substrate S may be seated on the support surface 112 of the receiving recess 112 of the support plate 110.

Then, a process gas may be supplied into the chamber 20 through the gas supply tube 50, plasma may be generated within the chamber 20, and then, an etch process may be performed on an object layer on the photomask substrate S.

When a plasma source power is applied to the upper electrode 40, an electromagnetic field induced by the upper electrode 40 may be applied to a source gas supplied into the chamber 20 to generate plasma. When a bias power is applied to a lower electrode of the substrate support 100, the support plate 110 may attract plasma atoms or ion generated within the chamber 20. Thus, the etch process may be performed on the object layer on the substrate S.

Then, after the etch process is performed, the substrate S may be unloaded from the chamber 20.

The above substrate processing apparatus may be applied to methods of manufacturing a photomask or a semiconductor device such as a logic device or a memory device. For example, the semiconductor device may include logic devices such as central processing units (CPUs), main processing units (MPUs), or application processors (APs), volatile memory devices such as DRAM devices or SRAM devices, or non-volatile memory devices such as flash memory devices, PRAM devices, MRAM devices, ReRAM devices, or the like.

By way of summation and review, in a leveling process of the lift pins, an operator could adjust heights of the lift pins by manually rotating fastening screws in lower portions of the lift pines. Because the work precision varies depending on the skill of the operator, the accuracy or the time of the leveling could be changed. In addition, if an error between heights of the lift pins were to occur, equipment may be required to be stopped and/or vacuum may be removed thereby lowering the operation rate of the equipment.

According to example embodiments, for leveling of lift pins, a plurality of the lift pins may be raised and a leveling sensor may be on the raised lift pins. A horizontal state of the lift pins may be detected based on measurements (roll (φ) and pitch (θ)) representing rotations with respect to a ground surface, e.g., a reference plane (Ps) from the leveling sensor, and travel distances of the lift pins for aligning the lift pins in a horizontal plane may be calculated. The lift pins may be moved by the calculated travel distances to align the lift pins in the horizontal plane.

Accordingly, by using a mask-type or wafer-type leveling sensor, the leveling of the lift pins may be automatically performed without stopping equipment and removing vacuum state.

Further, by adjusting the lift pins to converge on an average height of the lift pins, during leveling of the lift pins, the lift pins may be prevented from deviating from a limit height.

One or more embodiments may provide a lift pin alignment method capable of precisely and rapidly aligning lift pins.

One or more embodiments may provide a lift pin alignment apparatus for performing the lift pin alignment method.

One or more embodiments may provide a substrate processing apparatus including the lift pin alignment apparatus.

One or more embodiments may provide a lift pin alignment method for aligning heights of lift pins that are movable upwardly and downwardly in a substrate plate.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A substrate processing apparatus, comprising:
a chamber to provide a space for processing a substrate;
a substrate plate within the chamber and on which the substrate is seatable;
a plurality of lift pins protruding from within the substrate plate to support the substrate, the plurality of lift pins being configured to move upwardly and downwardly;
a leveling sensor configured to be loadable in the chamber on the plurality of lift pins that protrude from the substrate plate;
a controller configured to receive measurement values of roll (φ) and pitch (θ) representing an angle of a plane of the plurality of lift pins from the leveling sensor to calculate a rotation matrix (T) of the plane from the measurement values of roll (φ) and pitch (θ), to calculate travel distances of the lift pins for leveling the plane to be parallel with a horizontal reference plane by using the rotation matrix (T), and to output a lift pin control signal for aligning the plurality of lift pins in a horizontal plane; and
a lift pin driver configured to move the plurality of lift pins according to the lift pin control signal.

2. The substrate processing apparatus as claimed in claim 1, wherein the controller is configured to calculate a first rotation matrix (Rx) rotated by the roll (φ) about an X axis and a second rotation matrix (Ry) rotated by the pitch (θ) about a Y axis and to multiply the second rotation matrix (Ry) and the first rotation matrix (Rx) to obtain the rotation matrix (T).

3. The substrate processing apparatus as claimed in claim 2, wherein the first rotation matrix (Rx) is represented by following equation (1), the second rotation matrix (Ry) is represented by following equation (2), and the rotation matrix (T) is represented by following equation (3):
$$\begin{matrix}Rx = [ \begin{matrix}1 & 0 & 0 \\ 0 & cos ϕ & sin ϕ \\ 0 & - sin ϕ & cos ϕ\end{matrix} ] & Equation ( 1 ) \\ Ry = [ \begin{matrix}cos θ & 0 & - sin θ \\ 0 & 1 & 0 \\ sin θ & 0 & cos θ\end{matrix} ] & Equation ( 2 ) \\ T = RyRx . & Equation ( 3 )\end{matrix}$$

4. The substrate processing apparatus as claimed in claim 1, wherein the travel distances of the plurality of lift pins are distances in a vertical direction from the horizontal plane.

5. The substrate processing apparatus as claimed in claim 1, wherein the controller is configured to calculate final travel distances of the plurality of lift pins such that heights of the plurality of lift pins converge on an average height of the plurality of lift pins.

6. The substrate processing apparatus as claimed in claim 5, wherein the controller is configured to calculate the final travel distances by subtracting a mean value of the plurality of lift pins from the travel distances respectively.

7. The substrate processing apparatus as claimed in claim 1, wherein the controller is configured to determine an alignment state of the leveling sensor on the substrate plate.

8. The substrate processing apparatus as claimed in claim 7, wherein the controller is configured to determine whether a sliding direction of the leveling sensor is aligned with XYZ coordinates of the substrate plate.

9. The substrate processing apparatus as claimed in claim 1, wherein, after the plurality of lift pins are moved by the calculated travel distance, the controller is configured to receive measurement values of roll (φ) and pitch (θ) from the leveling sensor and to determine whether the plane of the plurality of lift pins is within a horizontal reference range.

10. The substrate processing apparatus as claimed in claim 1, wherein the leveling sensor has a shape corresponding to a photomask substrate or a wafer.

11. A substrate processing apparatus, comprising:
a chamber to provide a space for processing a substrate;
a substrate plate within the chamber and on which the substrate is seatable;
a plurality of lift pins protruding from within the substrate plate, the plurality of lift pins being configured to move upwardly and downwardly;
a leveling sensor configured to be loadable in the chamber on the plurality of lift pins that protrude from the substrate plate;
a controller configured to calculate an inclination of a plane of the plurality of lift pins with respect to a horizontal reference plane based on sensing values from the leveling sensor and to output a lift pin control signal for leveling the plurality of lift pins in a horizontal plane; and
a lift pin driver configured to move the plurality of lift pins by travel distances according to the lift pin control signal.

12. The substrate processing apparatus as claimed in claim 11, wherein the leveling sensor is configured to transmit measurement values of roll (φ) and pitch (θ) to the controller.

13. The substrate processing apparatus as claimed in claim 12, wherein the leveling sensor is configured to transmit the measurement values to the controller in real time via wireless communication.

14. The substrate processing apparatus as claimed in claim 12, wherein the controller is configured to calculate a first rotation matrix (Rx) rotated by roll (φ) about an X axis from the measurement value of roll (φ) and a second rotation matrix (Ry) rotated by a pitch (θ) about an Y axis from the measurement value of pitch (θ) and to multiply the second rotation matrix (Ry) and the first rotation matrix (Rx) to obtain a rotation matrix (T).

15. The substrate processing apparatus as claimed in claim 11, wherein the travel distances of the plurality of lift pins are distances in a vertical direction from the horizontal plane.

16. The substrate processing apparatus as claimed in claim 11, wherein the controller is configured to calculate final travel distances of the plurality of lift pins such that heights of the plurality of lift pins converge on an average height of the plurality of lift pins.

17. The substrate processing apparatus as claimed in claim 16, wherein the controller is configured to calculate the final travel distances by subtracting a mean value of the plurality of lift pins from the travel distances respectively.

18. The substrate processing apparatus as claimed in claim 11, wherein the controller is configured to determine an alignment state of the leveling sensor on the substrate plate.

19. The substrate processing apparatus as claimed in claim 18, wherein the controller is configured to determine whether a sliding direction of the leveling sensor is aligned with XYZ coordinates of the substrate plate in order to select the alignment state of the leveling sensor.

20. A lift pin alignment apparatus, comprising:
a leveling sensor on a plurality of lift pins protruding from a substrate plate to detect an inclination of a plane of the lift pins with respect to a horizontal reference plane;
a controller configured to calculate the inclination of the plane of the lift pins with respect to the horizontal reference plane based on sensing values from the leveling sensor and to output a lift pin control signal for leveling the lift pins in a horizontal plane; and
a lift pin driver configured to move the lift pins by travel distances according to the lift pin control signal.
